(19) United States
(12) Patent Application Publication
(10) Pub. No.: US 2009/0197384 A1
(43) Pub. Date: Aug. 6, 2009

(54) SEMICONDUCTOR MEMORY DEVICE AND METHOD FOR MANUFACTURING SEMICONDUCTOR MEMORY DEVICE

(75) Inventor: Shinpei IIJIMA, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC., Tokyo (JP)

(21) Appl. No.: 12/423,905

(22) Filed: Apr. 15, 2009

Related U.S. Application Data
(62) Division of application No. 11/402,061, filed on Apr. 12, 2006.

(30) Foreign Application Priority Data
Apr. 14, 2005 (JP) 2005-117603

(51) Int. Cl. H01L 21/02

(52) U.S. Cl. 438/386; 257/E21.008

(57) ABSTRACT

According to an aspect of the present invention, there is provided a semiconductor memory device. The semiconductor memory device is provided with an insulator and a capacitor. The capacitor is provided with a lower electrode provided with an inner portion and an outer portion, a dielectric portion on the lower electrode, and an upper electrode on the dielectric portion. The inner portion is provided with a lower part and an upper part upwardly extending from the lower part. The insulator laterally holds the lower part. The outer portion is arranged on the insulator and is electrically connected with the upper part.

### BACKGROUND OF THE INVENTION

This invention relates to a semiconductor memory device comprising a capacitor and a method for manufacturing the same.

In a DRAM, each memory cell typically includes an access transistor coupled to a storage capacitor. In order to fabricate high density dynamic random access memories (DRAMs), the storage capacitors must take up less planar area in the memory cells. As storage capacitors are scaled down in dimensions, a sufficiently high storage capacity must be maintained. Efforts to maintain storage capacity have concentrated on building three-dimensional capacitor structures that increase a capacitor surface area. The increased surface area provides for increased storage capacity. Three-dimensional capacitor structures include trench capacitors and stacked capacitors.

For stacked capacitors, a storage node of the capacitor generally extends significantly above a surface of an underlying substrate in order to provide a large surface area and thus sufficient storage capacity. This leads to topological problems in the formation of subsequent layers in the DRAM. Such topological problems are reduced by a use of crown-type stacked capacitors that increase surface area of the storage node while minimizing height.

The fabrication of the crown-type capacitor requires the storage node stably stands on the substrate during processes. Exemplary solutions are described in JP-A 2003-224210 and JP-A 2003-142605.

### SUMMARY OF THE INVENTION

Therefore, it is an object of the present invention to provide a semiconductor memory device comprising an improved capacitor which stably stands on the substrate during processes.

According to an aspect of the present invention, there is provided a semiconductor memory device, comprising an insulator and a capacitor. The capacitor comprises a lower electrode provided with an inner portion and an outer portion, a dielectric portion on the lower electrode, and an upper electrode on the dielectric portion. The inner portion comprises a lower part and an upper part upwardly extending from the lower part. The insulator laterally holds the lower part. The outer portion is arranged on the insulator and is electrically connected with the upper part.

According to another aspect of the present invention, there is provided a method for manufacturing a semiconductor memory device comprising a capacitor provided with a lower electrode, a dielectric portion and an upper electrode. The method comprises providing a semiconductor substrate comprising a first insulator, forming a second insulator on the first insulator, forming an outer portion mounted on the second insulator, forming a hole portion downwardly extending via the outer portion and the second insulator, forming an inner portion upwardly extending via the hole portion and being in contact with the outer portion at the hole portion, wherein the inner portion and the outer portion constitute the lower electrode, exposing at least a part of the lower electrode, forming the dielectric portion on the exposed part of the lower electrode, and forming the upper electrode on the dielectric portion.

These and other objects, features and advantages of the present invention will become more apparent upon reading of the following detailed description along with the accompanied drawings.

### BRIEF DESCRIPTION OF THE DRAWINGS

FIG. 1 is a partial sectional view of the semiconductor memory device of an embodiment of the present invention;

FIG. 2 is a partial sectional view of the capacitor of FIG. 1;

FIG. 3 is a partial sectional view of a capacitor of another embodiment of the present invention;

FIG. 4 is a partial sectional view of the capacitor of FIG. 2 at a processing step;

FIG. 5 is a partial sectional view of the capacitor of FIG. 2 at a processing step subsequent to that illustrated by FIG. 4;

FIG. 6 is a partial sectional view of the capacitor of FIG. 2 at a processing step subsequent to that illustrated by FIG. 5;

FIG. 7 is a partial sectional view of the capacitor of FIG. 2 at a processing step subsequent to that illustrated by FIG. 6;

FIG. 8 is a partial sectional view of the capacitor of FIG. 2 at a processing step subsequent to that illustrated by FIG. 7;

FIG. 9 is a partial sectional view of the capacitor of FIG. 2 at a processing step subsequent to that illustrated by FIG. 8;

FIG. 10 is a partial sectional view of the capacitor of FIG. 2 at a processing step subsequent to that illustrated by FIG. 9;

FIG. 11 is a partial sectional view of the capacitor of FIG. 2 at a processing step subsequent to that illustrated by FIG. 10;

FIG. 12 is a partial sectional view of the capacitor of FIG. 2 at a processing step subsequent to that illustrated by FIG. 11;

FIG. 13 is a partial sectional view of the capacitor of FIG. 2 at a processing step subsequent to that illustrated by FIG. 12;

FIG. 14 is a partial sectional view of the capacitor of FIG. 3 at a processing step subsequent to that illustrated by FIG. 9; and

FIG. 15 is a partial sectional view of the capacitor of FIG. 3 at a processing step subsequent to that illustrated by FIG. 14.

### DESCRIPTION OF PREFERRED EMBODIMENTS

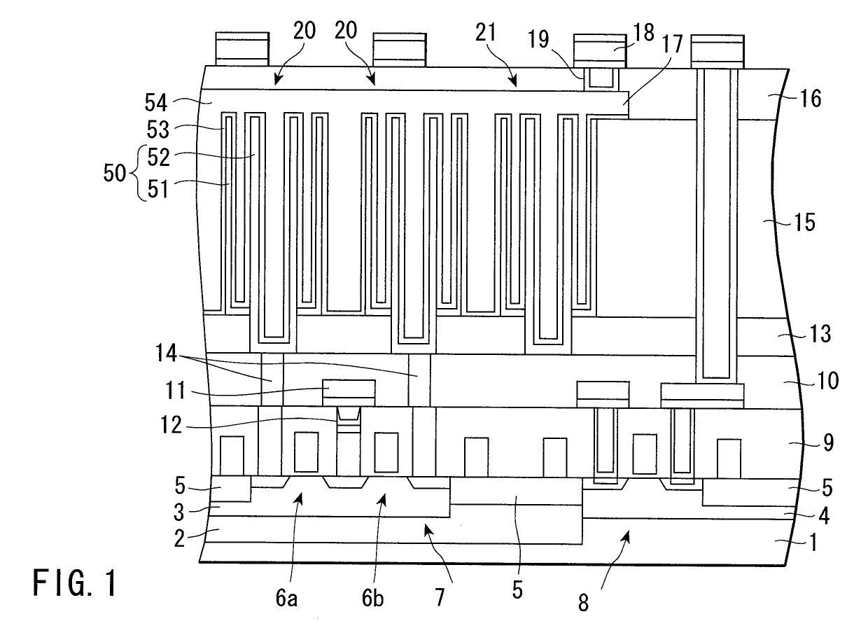

FIG. 1 illustrates a DRAM comprising a capacitor. Cross-hatching in FIG. 1 is omitted for the sake of clarity. The DRAM comprises a p-type silicon substrate 1 provided with an n-well region 2, a first p-well region 3, a second p-well region 4 and an isolation region 5. The n-well region 2 is formed in the p-type silicon substrate 1. The first p-well region 3 is formed in the n-well region 2. The second p-well region 4 is formed in the p-type silicon substrate 1. The isolation region 5 is arranged to isolate the first p-well region 3 and the second p-well region 4, and also arranged to divide the first p-well region 3 and the second p-well region 4 into smaller regions respectively. The DRAM has a region of memory cell array 7 and a region of peripheral circuit 8. The first p-well region 3 is arranged in the region of memory cell array 7. The second p-well region 4 is arranged in the region of peripheral circuit 8.

The p-type silicon substrate 1 is covered by a lower insulator 9. The lower insulator 9 is covered by a first insulator 10. In the first p-well region 3 and the lower insulator 9, a first switching transistor 6a and a second switching transistor 6b are provided.

In the first insulator 10, a bit line 11 is arranged. In the lower insulator 9, a bit line contact 12 is formed to electrically connect the bit line 11 with the first switching transistor 6a and the second switching transistor 6b. The first insulator 10 and the bit line 11 are covered by a second insulator 13. In this embodiment, the second insulator 13 may be made of silicon nitride or silicon oxynitride.

Within the region of memory cell array 7, a plurality of crown-type capacitors 20 are arranged on the first insulator 10 and the second insulator 13. The crown-type capacitor 20 comprises a lower electrode 50, a dielectric portion 53 and an upper electrode 54. In the lower insulator 9 and the first insulator 10, a conductive plug 14 is arranged to electrically connect the lower electrode 50 with the first switching transistor 6a or the second switching transistor 6b.

The first switching transistor 6a and the second switching transistor 6b serve to switch connections between the bit line 11 and the lower electrodes 50.

In the region of peripheral circuit 8, the second insulator 13 is covered by a third insulator 15. Between the third insulator 15 and the crown-type capacitors 20, a plurality of dummy trench-like capacitors 21 are arranged to surround the crown-type capacitors 20. Each dummy trench-like capacitor 21 has the same lower electrode as the crown-type capacitor 20. The third insulator 15 and the upper electrode 54 of the crown-type capacitor 20 are covered by an upper insulator 16.

The upper electrode 54 is in contact with a lead line 17 extending from the region of memory cell array 7 into the region of peripheral circuit 8. On the upper insulator 16, a line 18 is arranged. In the upper insulator 16, a contact plug 19 is formed to electrically connect the lead line 17 with the line 18.

The DRAM may include other insulators, contact plugs and lines, and so on.

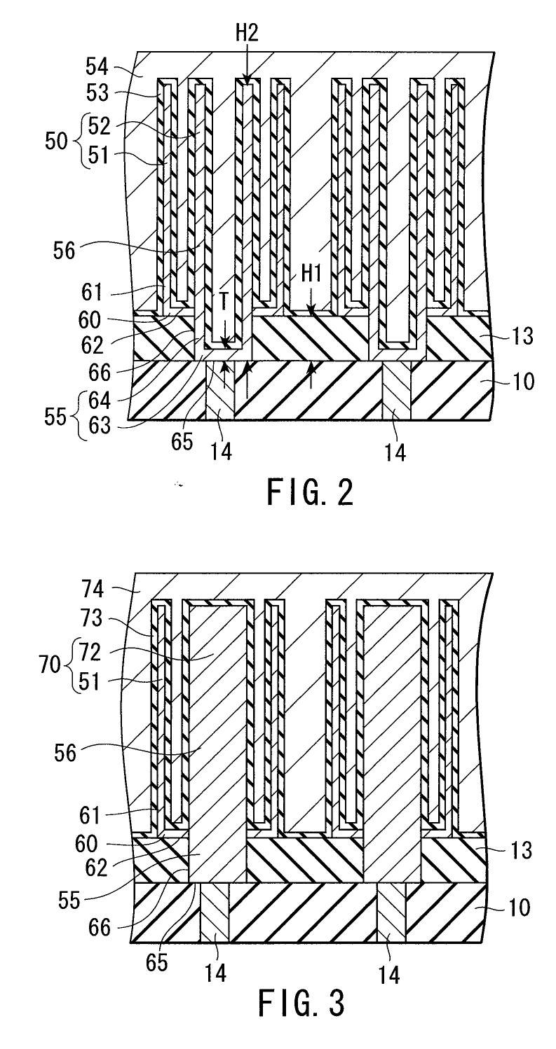

Referring to FIG. 2, the lower electrode 50 is provided with an outer portion 51 and an inner portion 52. The inner portion 52 comprises a lower part 55 and an upper part 56. The lower part 55 is arranged on the first insulator 10 and is in contact with the conductive plug 14. The lower part 55 is laterally surrounded by and held by the first insulator 13. The lower part 55 comprises a plate-like portion 63 and a cylindrical sidewall portion 64. The plate-like portion 63 has a bottom surface 65 which is laid on the first insulator 10 and is in contact with the conductive plug 14. The bottom surface 65 has a circular shape. The cylindrical sidewall portion 64 has a side surface 66 upwardly extending from the bottom surface 65. The side surface 66 is in contact with the second insulator 13. The upper part 56 upwardly extends from the cylindrical side wall portion 64 of the lower part 55.

In this embodiment, a height “H1” of the lower part 55 is equal to or more than five times a thickness “T” of the plate-like portion 63 so as to prevent the lower electrode 50 from collapsing. In addition, the height “H1” is preferably equal to or less than fifteen times the thickness “T”, so as to ensure a sufficient capacitance of the crown-type capacitor 20.

Preferably, the height “H1” is equal to or more than one-sixth of the height “H2” of the inner portion 52 so as to prevent the lower electrode 50 from collapsing by penetration of hydrofluoric-acid-containing solution into an interface of the lower electrode 50 and the second insulator 13 even during an etching process to expose the lower electrode 50. In addition, the height “H1” is preferably equal to or less than one-third of “H2”, so as to ensure a sufficient capacitance of the crown-type capacitor 20.

The outer portion 51 is arranged on the second insulator 13 and is in contact with the upper part 56 of the inner portion 52. The outer portion 51 comprises an upper supporting portion 60 mounted on the second insulator 13, and an outer sidewall portion 61 upwardly extends from the upper supporting portion 60. The upper supporting portion 60 laterally extends from the upper part 56 of the inner portion 52. The outer portion 51 laterally surrounds the inner portion 52.

The dielectric portion 53 is arranged over the lower electrode 50 along surfaces of the inner portion 52 and the outer portion 51 except surfaces which are in contact with the second insulator 13, the first insulator 10 or the conductive plug 14. The dielectric portion 53 is partially in contact with the second insulator 13. The upper electrode 54 is arranged over the dielectric portion 53.

The lower electrode 50 and the conductive plug 14 of this embodiment are made of polysilicon. The lower electrode 50 may be made of metal or metal compound. If the lower electrode 50 is made of metal or metal compound, a barrier layer and a metal silicide layer are arranged between the conductive plug 14 and the lower electrode 50. The metal silicide layer is arranged on the plug material and may be made of titanium silicide. The barrier layer is arranged on the metal silicide layer and may be made of titanium nitride.

In another embodiment illustrated in FIG. 3, the lower electrode 70 comprises the outer portion 51 and an inner portion 72. The inner portion 72 has a pillar shape.

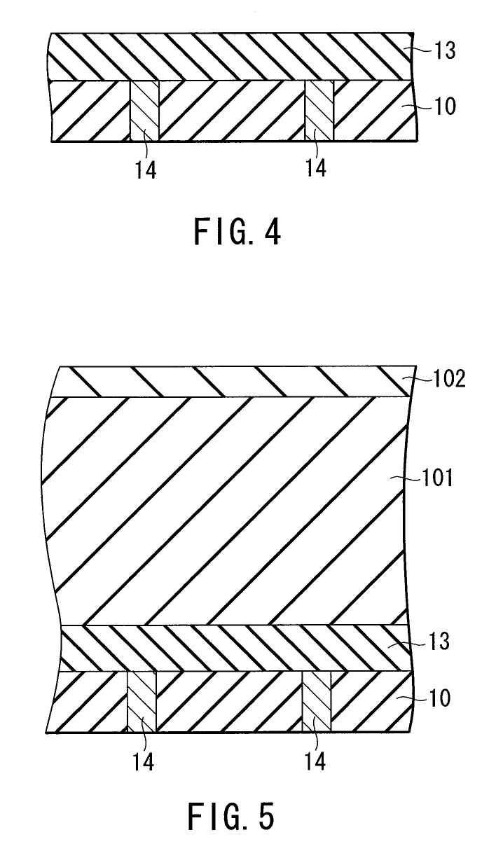

FIGS. 4 to 13 are partial sectional views of the manufacturing steps for the crown-type capacitor 20 according to a preferred embodiment of the present invention.

Referring to FIG. 4, after provision of the semiconductor substrate 1 including the first insulator 10 made of silicon oxide, the conductive plug 14 made of polysilicon is formed to extend from a lower surface to an upper surface of the first insulator 10. Next, the second insulator 13 made of silicon nitride is deposited on the first insulator 10 and the conductive plug 14. The second insulator 13 is formed by thermal chemical vapor deposition (thermal CVD) using a dichlorosilane (SiH₂Cl₂) gas and an ammonia (NH₃) gas as source gases. In this embodiment, the thickness of the second insulator 13 is 300 nm. The second insulator 13 may be formed by plasma CVD. The second insulator 13 may be made of silicon oxynitride (SiON); the source gas therefor may further include a N₂O gas.

Referring to FIG. 5, on the second insulator 13, a first sacrificial layer 101 made of silicon oxide is deposited. The first sacrificial layer 101 is formed by plasma CVD using a tetraethoxysilane (TEOS: Si(OC₂H₅)₄) gas and an oxygen gas as source gases. In this embodiment, the thickness of the first sacrificial layer 101 is 1200 nm. Next, on the first sacrificial layer 101, a hard mask 102 made of silicon is deposited. The hard mask 102 is formed by thermal CVD using a monosilane (SiH₄) gas as a source gas. In this embodiment, the thickness of the hard mask 102 is 500 nm. The hard mask 102 may be made of amorphous carbon.

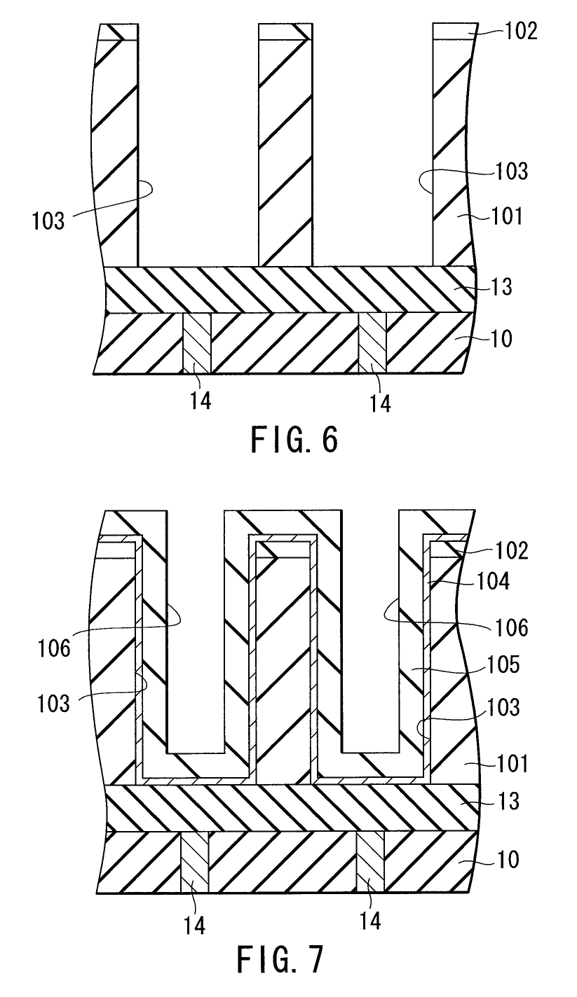

Referring to FIG. 6, on the hard mask 102, a photoresist is arranged and is patterned by photolithography to have a mask pattern which has a plurality of openings. Next, the hard mask 102 is dry etched using the photoresist as a mask so that the pattern of the photoresist is transferred onto the hard mask 102, wherein gas plasma used in the dry-etching process is generated by using a chlorine gas as a main component. Next, the first sacrificial layer 101 is etched to expose the second insulator 13 by anisotropic dry etching using the etched hard mask 102 as a mask, wherein the dry etching uses gas plasma whose source gases include an octafluorocyclopentene (C₅F₈) gas and an argon gas as main components. The first sacrificial layer 101 may be etched using an octafluorocyclobutane (C₄F₈) gas or other gases as the main components. As the result of the dry etching of the first sacrificial layer 101, an outer hole 103 is defined in the first sacrificial layer 101.

Referring to FIG. 7, on the whole area including an inner surface of the outer hole 103, a first conductive material 104 is formed. Forming the first conductive material 104 includes depositing amorphous silicon on the whole area. The amorphous silicon layer is formed by thermal CVD using a SiH₄ gas and a phosphine (PH₃) gas as source gases. Next, a heat treatment process is carried out for the thus-obtained intermediate product so that the amorphous silicon layer is changed into the first conductive material 104 made of polysilicon. In this embodiment, the thickness of the first conductive material 104 is 30 nm. Next, on the first conductive material, a second sacrificial layer 105 made of silicon oxide is deposited. The second sacrificial layer 105 is formed by thermal CVD using a SiH₄ gas and a N₂O gas as source gases. As the result of the deposition, an inner hole 106 is defined in the outer hole 103 as shown in FIG. 7. In this embodiment, the thickness of the second sacrificial layer 105 is 30 nm.

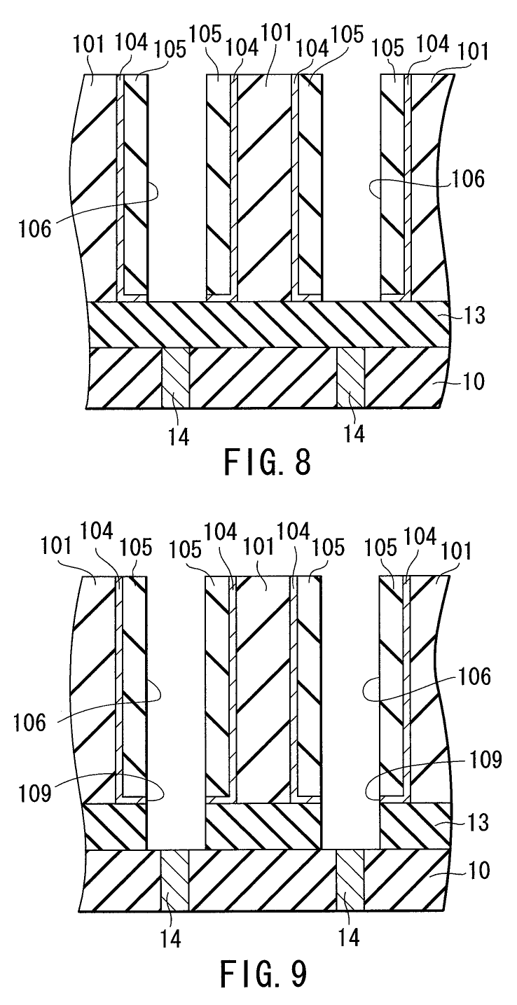

Referring to FIG. 8, the second sacrificial layer 105, the first conductive material 104 and the hard mask 102 are etched back by gas plasma etching using a fluorine-containing gas under a condition where an etching rate of the second sacrificial layer 105 and that of the first conductive material 104 are about the same. As the result of the etching, the inner hole 106 is downwardly elongated to expose the second insulator 13, and a top of the first sacrificial layer 101 and a top of the first conductive material 104 are exposed. The second sacrificial layer 105 and the first conductive material 104 may be etched under different conditions.

Referring to FIG. 9, the second insulator 13 exposed in the inner hole 106 is etched back by anisotropic dry etching using a fluorine-containing gas. As the result of the anisotropic dry etching, the inner hole 106 is downwardly elongated so that the inner hole 106 is provided with a hole portion 109 which is formed in the second insulator 13 through the first conductive material 104. If the first sacrificial layer 101 and the second sacrificial layer 105 are also etched during the etching process of the second insulator 13 so that a projection of the first conductive material 104 is formed, the projection may be planarized by CMP. As the result of the anisotropic dry etching, oxide films of about 1 nm are naturally formed an exposed portion of the conductive plug 14 and another exposed portion of the first conductive material 104 in the inner hole 106.

Referring to FIG. 10, the substrate is soaked in a hydrofluoric-acid-containing solution to remove the naturally-formed oxide films. Next, a second conductive material 107 made of polisilicon is formed over the whole surface. The second conductive material 107 is formed under the same condition of the first conductive material 104. The second conductive material 107 has the thickness of 30 nm which is one-tenth of the thickness of the second insulator 13, in this embodiment. Next, on the second conductive material 107, a third sacrificial layer 108 is deposited so that the inner hole 106 is filled with the third sacrificial layer 108. The third sacrificial layer 108 is formed under the same condition of the second sacrificial layer 105.

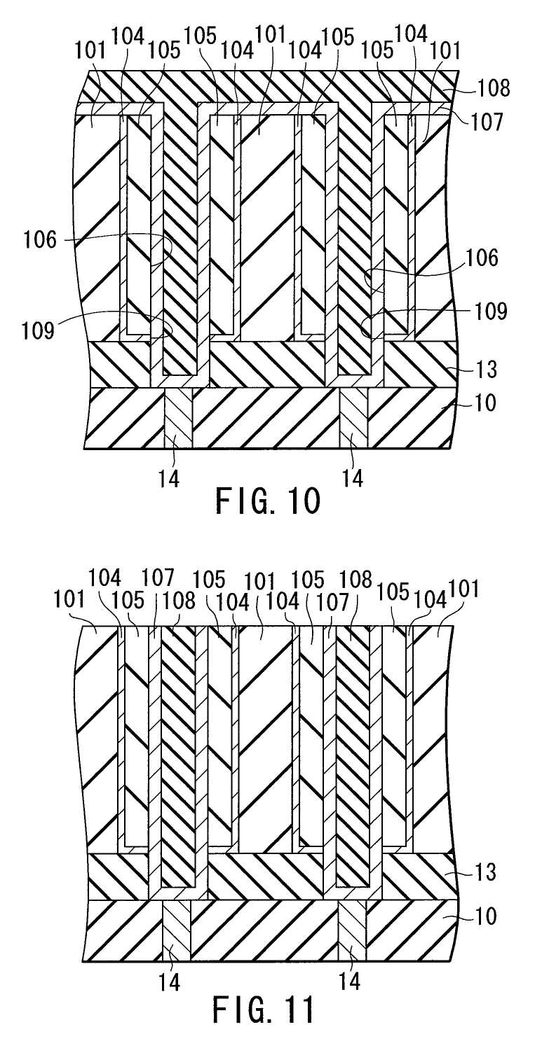

Referring to FIG. 11, the third sacrificial layer 108 and the second conductive material 107 are partially removed by CMP until the top of the second sacrificial layer 105 is exposed.

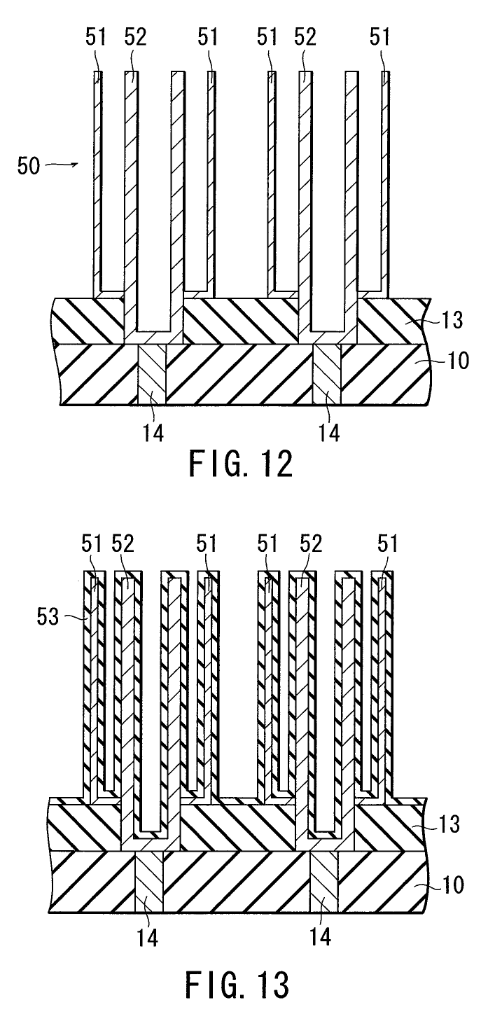

Referring to FIG. 12, the first sacrificial layer 101, the second sacrificial layer 105 and the third sacrificial layer 108 are completely removed by using a hydrofluoric acid solution. For example, the second sacrificial layer 105 of 1200 nm is removed in about 10 minutes by using a 10% solution of hydrofluoric acid. The first sacrificial layer 101, the second sacrificial layer 105 and the third sacrificial layer 108 may also be removed by using a buffer solution mainly made of hydrofluoric acid which contains ammonium fluoride (NH₄F). Thus, the lower electrode 50 comprised of the outer portion 51 and the inner portion 52 is formed, as shown in FIG. 12.

Referring to FIG. 13, on the lower electrode 50, a dielectric portion 53 is formed. In this embodiment, the dielectric portion 53 is made of a thermal nitride film and a tantalum oxide film. The thermal nitride film is a silicon nitride of about 1 nm on the lower electrode 50. The tantalum oxide film of 9 nm is deposited over the silicon nitride. The tantalum oxide film is formed by CVD using a tantalum pentaethoxide (PET: Ta(OC₂H₅)₅) gas and an oxygen gas as source gases. Next, the tantalum oxide film is crystallized by heat treatment in an N₂O atmosphere. Instead of the tantalum oxide film, a single layer film of aluminum oxide or a multilayered film made of aluminum oxide and hafnium oxide may also be used as components of the dielectric portion 53. For example, aluminum oxide is formed by atomic layer deposition using a trimethylaluminum (TMA: Al(CH₃)₃) gas and a H₂O gas as source gases at 350 degree. Likewise, the tantalum oxide film and the hafnium oxide film may be formed by atomic layer deposition. Atomic layer deposition of the dielectric portion 53 can be carried out at lower temperature than CVD while oxidation of the lower electrode 50 is suppressed. If the dielectric portion 53 is formed by atomic layer deposition, titanium nitride or tungsten may be used as a material of the lower electrode 50.

Next, as shown in FIG. 2, the upper electrode 54 made of titanium nitride is deposited on the dielectric portion 53. The upper electrode 54 is formed by CVD using a titanium chloride (TiCl₄) gas and an ammonia (NH₃) gas as source gases. The upper electrode 54 may be deposited by atomic layer deposition. On the upper electrode 54, a tungsten layer of 200 nm may be formed by sputtering so as to make the upper electrode 54 thicker and lower a resistance of the upper electrode 54.

If the dielectric portion 53 is deposited by atomic layer deposition, the lower electrode 50 of an embodiment of the present invention may be made of metal or metal compound. If the lower electrode 50 is made of metal or metal compound, a barrier layer is preferably formed on the conductive plug 14, and a metal silicide layer is preferably formed on the barrier layer before forming the second insulator 13 on the barrier layer. The metal silicide layer may be made of titanium silicide. The barrier layer may be made of titanium nitride. Forming the barrier layer and the metal silicide layer may be carried out after the exposure of the conductive plug 14 as illustrated in FIG. 9.

Next, an explanation will be made about the manufacturing method of the semiconductor memory device shown in FIG. 3 The manufacturing method includes the same processes as shown in FIGS. 4 to 9.

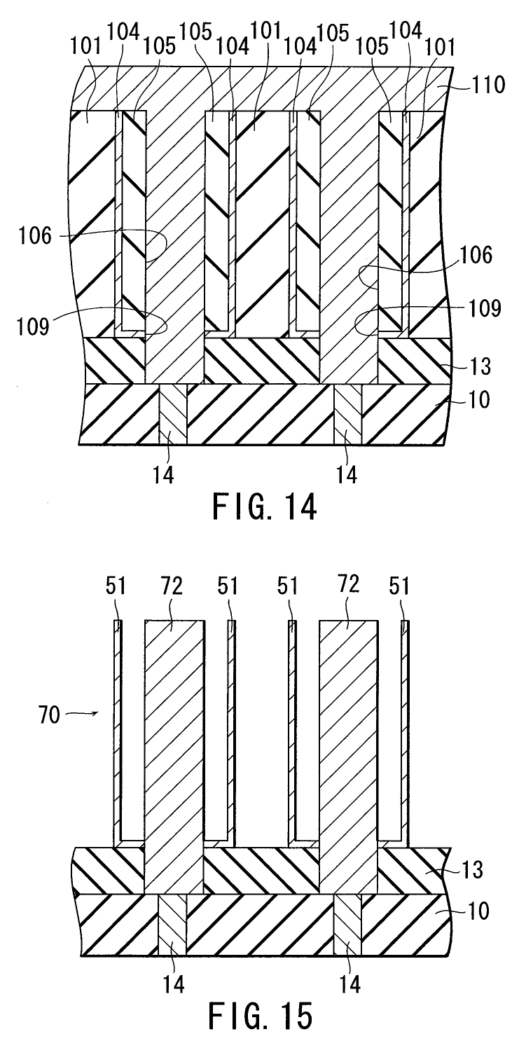

Referring to FIG. 14, a second conductive material 110 made of polysilicon is formed over the whole surface by the thermal CVD. Then, the second conductive material 110 is partially removed by the CMP until the top of the second sacrificial layer 105 is exposed.

Referring to FIG. 15, the first sacrificial layer 101 and the second sacrificial layer 105 are completely removed by using the hydrofluoric acid solution.

Referring to FIG. 3, a dielectric portion 73 made of the thermal nitride film and the tantalum oxide film is deposited by the CVD on the lower electrode 70 provided with the outer portion 51 and the inner portion 72. Next, an upper electrode 74 made of titanium nitride is deposited on the dielectric portion 73 by the CVD.

This application is based on Japanese Patent Application serial no. 2005-117603 filed in Japan Patent Office on Apr. 14, 2005, the contents of which are hereby incorporated by reference.

Although the present invention has been fully described by way of example with reference to the accompanying drawings, it is to be understood that various changes and modifications will be apparent to those skilled in the art. Therefore, unless otherwise such changes and modifications depart from the scope of the present invention hereinafter defined, they should be constructed as being included therein.

1-11. (canceled)

12. A method for manufacturing a semiconductor memory device comprising a capacitor provided with a lower electrode, a dielectric portion and an upper electrode, the method comprising:
providing a semiconductor substrate comprising a first insulator;
forming a second insulator on the first insulator;
forming an outer portion mounted on the second insulator;
forming a hole portion downwardly extending via the outer portion and the second insulator;
forming an inner portion upwardly extending via the hole portion and being in contact with the outer portion at the hole portion, wherein the inner portion and the outer portion constitute the lower electrode;
exposing at least a part of the lower electrode;
forming the dielectric portion on the exposed part of the lower electrode; and
forming the upper electrode on the dielectric portion.

13. The method according to claim 12, wherein the inner portion includes a lower part and an upper part, and the forming of the inner portion is carried out so that the lower part is laterally surrounded by the second insulator and the upper part upwardly extends from the lower part, and that a height of the inner portion is from one-sixth to one-third as large as a height of the lower part.

14. The method according to claim 12, wherein the forming the outer portion comprises:
forming a first sacrificial layer on the second insulator, wherein the first sacrificial layer has an upper surface and a lower surface;
forming an outer hole downwardly extending via the first sacrificial layer from the upper surface to the lower surface;
forming a first conductive material to cover an inner surface of the outer hole with the first conductive material;
forming a second sacrificial layer to cover the first conductive material with the second sacrificial layer so that the second sacrificial layer defines an inner hole within the outer hole,
elongating the inner hole downwardly to expose the second insulator by partially removing the second sacrificial layer and the first conductive material so as to form the outer portion made of the first conductive material; and
further elongating the elongated inner hole downwardly to expose the first insulator by partially removing the second insulator.

15. The method according to claim 14, wherein the providing the inner portion includes forming the inner portion made of a second conductive material covering the inner surface of the inner hole.

16. The method according to claim 15, wherein the forming of the inner portion is carried out so that a height of the lower part of the inner portion is from five to fifteen times as thick as a thickness of the inner portion.

17. The method according to claim 14, wherein the providing the inner portion includes forming the inner portion made of a second conductive material filling the inner hole.

18. The method according to claim 12, wherein the second insulator is made of silicon nitride or silicon oxynitride.

19. The method according to claim 12, wherein the providing of the semiconductor substrate includes forming a conductive plug in the first insulator, wherein the conductive plug is electrically connected with the inner portion of the lower electrode, and the conductive plug and the lower electrode are made of polysilicon.

20. The method according to claim 12, wherein the providing of the semiconductor substrate includes:
forming a conductive plug in the first insulator;
forming a metal silicide layer on the conductive plug in the first insulator; and
forming a barrier layer on the metal silicide layer in the first insulator, wherein the lower electrode is formed on the barrier layer by using metal or metal compound.
